(19) United States
(12) Patent Application Publication
(10) Pub. No.: US 2026/0157081 A1
(43) Pub. Date: Jun. 4, 2026

(54) DISPLAY PANEL AND DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Xiaojing HU, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 18/706,352

(22) PCT Filed: Apr. 16, 2024
(86) PCT No.: PCT/CN2024/087889

§ 371 Date: Apr. 30, 2024

(30) Foreign Application Priority Data
Apr. 7, 2024 (CN) 202410415743.9

(51) Int. Cl. H10K 59/80

(52) U.S. Cl. CPC H10K 59/873

(57) ABSTRACT

The embodiment of the present invention discloses a display panel and a display device. The display panel includes a display layer, a cover layer, and a first bonding layer located therebetween. The cover layer includes a protection sublayer, the protection sublayer is located on a side of the first bonding layer away from display layer. A hardness of a surface of a side of the protection sublayer away from first bonding layer is greater than or equal to 6H and is less than or equal to 9H. A water drop angle of a surface of the cover layer and/or the display layer contacting the first bonding layer is greater than or equal to 100 degrees.

### FIELD OF INVENTION

The present invention relates to a field of displays, especially to a display panel and a display device.

### BACKGROUND OF INVENTION

With the development of display technology, people have raised higher requirements for the product quality and performance of display panels and display devices. Conventional display panels, such as foldable types, often encounter issues like surface scratches and damage from drops during use. Repair or replacement typically requires separating the cover layer from the display layer. In conventional display panels, the replaceable cover layer typically consists of film layers with lower hardness and modulus (shown as the first polymer protective layer 111′ and second polymer protective layer 112′ in FIG. 1) as the outermost layer, while the hard protective layer (shown as element 113′ in FIG. 1) is directly bonded to the display layer 120′ through a bonding layer 130′ and cannot be replaced, resulting in a poor user experience. When used with a stylus, the stylus easily leaves scratches on the outer surface of the cover layer, reducing the product quality of the display panel.

Therefore, there is an urgent need for a display panel and display device to address the aforementioned technical issues.

### SUMMARY OF INVENTION

The present invention provides a display panel and display device that can ease a technical issue that a replaceable cover layer in the conventional display panel employs a film layer with poor hardness and modulus as an outermost layer and results in poor user's feeling of use and scratches easily left on surfaces.

To solve the above issue, the present application technical solutions as follows:

The present invention provides a display panel, comprising:
a display layer;
a cover layer located on a light exiting side of the display layer; and
a first bonding layer located between the display layer and the cover layer;
wherein the cover layer comprises a protection sublayer, the protection sublayer is located on a side of the first bonding layer away from the display layer, a hardness of a surface of a side of the protection sublayer away from the first bonding layer is greater than or equal to 6H, and the hardness of the surface of the side of the protection sublayer away from the first bonding layer is less than or equal to 9H;
wherein a water drop angle of a surface of a side of the cover layer contacting the first bonding layer is greater than or equal to 100 degrees, and/or, a water drop angle of a surface of a side of the display layer contacting the first bonding layer is greater than or equal to 100 degrees.

The present invention also provides a display device comprising a display panel, and the display panel comprising:
a display layer;
a cover layer located on a light exiting side of the display layer; and
a first bonding layer located between the display layer and the cover layer;
wherein the cover layer comprises a protection sublayer, the protection sublayer is located on a side of the first bonding layer away from the display layer, a hardness of a surface of a side of the protection sublayer away from the first bonding layer is greater than or equal to 6H, and the hardness of the surface of the side of the protection sublayer away from the first bonding layer is less than or equal to 9H;
wherein a water drop angle of a surface of a side of the cover layer contacting the first bonding layer is greater than or equal to 100 degrees, and/or, a water drop angle of a surface of a side of the display layer contacting the first bonding layer is greater than or equal to 100 degrees.

### DESCRIPTION OF DRAWINGS

FIG. 1 is a schematic structural view of a conventional display panel;

FIG. 2 is a schematic structural view of the display panel provided by the embodiment of the present invention;

FIG. 3 is a first schematic structural view of a cover layer of the display panel provided by the embodiment of the present invention;

FIG. 4 is a second schematic structural view of the cover layer of the display panel provided by the embodiment of the present invention;

FIG. 5 is a third schematic structural view of the cover layer of the display panel provided by the embodiment of the present invention;

FIG. 6 is a structural schematic view of a protection sublayer of the display panel provided by the embodiment of the present invention; and

FIG. 7 is a schematic structural view of a display device provided by the embodiment of the present invention.

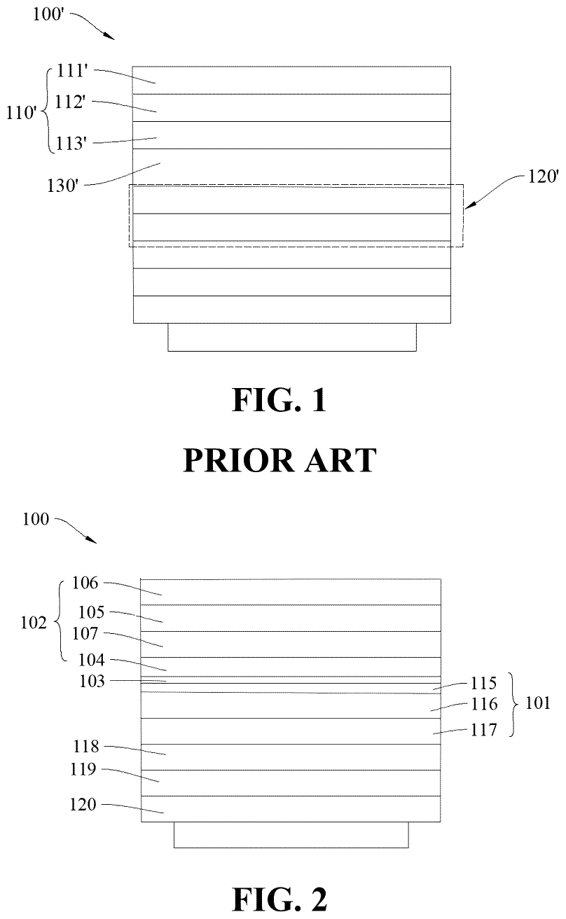

### DETAILED DESCRIPTION OF PREFERRED EMBODIMENTS

The present application provides a display panel and a display device. To make the objective, the technical solution, and the effect of the present application clearer and more explicit, the present application will be further described in detail below with reference to the accompanying drawings. It should be understood that the specific embodiments described here are only used to explain the present application instead of being used to limit the present application.

At present, a replaceable cover layer in a display panel utilizes a film layer with poor hardness and modulus as an outermost layer, and has a technical issue of a poor user's feeling of use and scratches easily left on surfaces.

With reference to FIGS. 2 to 6, the embodiment of the present invention provides a display panel 100, comprising:
a display layer 101;
a cover layer 102 located on the light exiting side of the display layer 101;
a first bonding layer 103 located between the display layer 101 and the cover layer 102;
wherein the cover layer 102 comprises a protection sublayer 105, the protection sublayer 105 is located on a side of the first bonding layer 103 away from the display layer 101, a hardness of a surface of a side of the protection sublayer 105 away from the first bonding layer 103 is greater than or equal to 6H, and the hardness of the surface of the side of the protection sublayer 105 away from the first bonding layer 103 is less than or equal to 9H;
a water drop angle of a surface of a side of the cover layer 102 contacting the first bonding layer 103 is greater than or equal to 100 degrees, and/or, a water drop angle of a surface of a side of the display layer 101 contacting the first bonding layer 103 is greater than or equal to 100 degrees.

In the embodiment of the present invention, the hardness of the surface of the side of the protection sublayer 105 away from the first bonding layer 103 is greater than or equal to 6H and is less than or equal to 9H. The configuration of the protection sublayer 105 improves a hardness of a side of the cover layer 102 away from the display layer 101 (namely, a side of the cover layer 102 contacted by a user), enhances the user's feeling of use and reduces surface scratches. Also, the protection sublayer 105 is located on a side of the display layer 101 away from first bonding layer 103, and can be separated from the display layer 101 and removed when the protection sublayer 105, which facilitates repair or replacement for the cover layer 102 and advantages maintaining the product quality of the display panel 100 and prolonging the usage lifespan of the display panel 100.

In the embodiment of the present invention, the water drop angle of the surface of the side of the cover layer 102 contacting the first bonding layer 103 is greater than or equal to 100 degrees such that the cover layer 102 is easily separated from the first bonding layer 103; and/or, the water drop angle of the surface of the side of the display layer 101 contacting the first bonding layer 103 is greater than or equal to 100 degrees such that the first bonding layer 103 is easily separated from the display layer 101. The above configuration facilitates lowering removal difficulty to the cover layer 102 for repair or replacement of the cover layer 102, and facilitates maintaining the product quality of the display panel 100 and prolonging the usage lifespan of the display panel 100.

The embodiment of the present invention disposes the protection sublayer 105 with a greater hardness on the cover layer 102 and makes the water drop angle of the surface of the cover layer 102 and/or the display layer 101 contacting the first bonding layer 103 greater than or equal to 100 degrees, thereby increasing a surface hardness of a side of the cover layer 102 away from display layer 101, enhances the user's feeling of use, and reduces surface scratches while lowering removal difficulty to the cover layer 102, to improve the product quality of the display panel.

Technical solutions of the present invention are described in combination with specific embodiments as follows.

In some embodiments, a difference between a hydrophobicity of the surface of the side of the display layer 101 contacting the first bonding layer 103 and a hydrophobicity of the surface of the side of the cover layer 102 contacting the first bonding layer 103 is utilized, which facilitates implementing separation of the display layer 101 from the first bonding layer 103, or, implementing separation of the cover layer 102 from the first bonding layer 103 to easily implement separation of the cover layer 102 from the display layer 101, lower the removal difficulty to the cover layer 102, and prolong the usage lifespan of the display panel.

In some embodiments, when the hydrophobicity of the surface of the side of the display layer 101 contacting the first bonding layer 103 is stronger than the hydrophobicity of the surface of the side of the cover layer 102 contacting the first bonding layer 103, the water drop angle of the surface of the side of the display layer 101 contacting the first bonding layer 103 is greater than or equal to 100 degrees. For example, the water drop angle can be 105 degrees, 108 degrees, 110 degrees, 115 degrees, 118 degrees, 120 degrees, etc. such that the surface of the side of the display layer 101 contacting the first bonding layer 103 has a sufficient hydrophobicity, thereby facilitating separation of the display layer 101 from the first bonding layer 103. The water drop angle can be obtained by a water drop angle meter.

In some embodiments, when a water drop angle of a surface of a side of the display layer 101 contacting the first bonding layer 103 is greater than or equal to 100 degrees, the water drop angle of the surface of the side of the cover layer 102 contacting the first bonding layer 103 is greater than or equal to 20 degrees, the water drop angle of the surface of the side of the cover layer 102 contacting the first bonding layer 103 is less than or equal to 50 degrees such that the surface of the side of the cover layer 102 contacting the first bonding layer 103 has sufficient hydrophilicity to form a sufficient bonding force between the cover layer 102 and the first bonding layer 103. Thus, when the cover layer 102 is separated from the display layer 101, the first bonding layer 103 is also removed without the first bonding layer 103 remaining on the light exiting side of the display layer 101.

With reference to FIGS. 2 to 3, 6, in some embodiments, when the water drop angle of the surface of the side of the display layer 101 contacting the first bonding layer 103 is greater than or equal to 100 degrees, the display layer 101 comprises a first sublayer 115, and a side of the first sublayer 115 near the first bonding layer 103 contacts the first bonding layer 103. Namely, a water drop angle of a surface of a side of the first sublayer 115 contacting the first bonding layer 103 is greater than or equal to 100 degrees.

In some embodiments, the first sublayer 115 can be an anti-fingerprint coating layer comprising oil resistance, anti-fingerprint, waterproof and other properties.

In some embodiments, material of the first sublayer 115 can be selected from at least one of fluorine-containing inorganic material and fluorine-containing organic material. For example, the material of the first sublayer 115 can be selected from fluorosilicates.

In some embodiments, when the hydrophobicity of the surface of the side of the display layer 101 contacting the first bonding layer 103 is weaker than the hydrophobicity of the surface of the side of the cover layer 102 contacting the first bonding layer 103, the water drop angle of the surface of the side of the cover layer 102 contacting the first bonding layer 103 is greater than or equal to 100 degrees. For example, the water drop angle can be 105 degrees, 108 degrees, 110 degrees, 115 degrees, 118 degrees, 120 degrees, etc. such that the surface of the side of the cover layer 102 contacting the first bonding layer 103 has a sufficient hydrophobicity, thereby facilitating separation of the cover layer 102 from the first bonding layer 103.

In some embodiments, when the water drop angle of the surface of the side of the cover layer 102 contacting the first bonding layer 103 is greater than or equal to 100 degrees, the water drop angle of the surface of the side of the display layer 101 contacting the first bonding layer 103 is greater than or equal to 20 degrees, and the water drop angle of the surface of the side of the display layer 101 contacting the first bonding layer 103 is less than or equal to 50 degrees such that the surface of the side of the display layer 101 contacting the first bonding layer 103 has sufficient hydrophilicity to form a sufficient bonding force between the display layer 101 and the first bonding layer 103. Thus, when the cover layer 102 is separated from the display layer 101, the first bonding layer 103 can be reserved completely and continuously to bond a replacement of the cover layer 102.

In some embodiments, the utilization of the hydrophobicity of the surface of the side of the display layer 101 contacting the first bonding layer 103 and the hydrophobicity of the surface of the side of the cover layer 102 contacting the first bonding layer 103 that are greater facilitates sequentially implementing separation of the cover layer 102 from the first bonding layer 103, and separation of the first bonding layer 103 from the display layer 101 layer by layer without the first bonding layer 103 remaining on the light exiting side of the display layer 101. At this time, the water drop angle of the surface of the side of the cover layer 102 contacting the first bonding layer 103 is greater than or equal to 100 degrees, and the water drop angle of the surface of the side of the display layer 101 contacting the first bonding layer 103 is greater than or equal to 100 degrees.

With reference to FIG. 4, in some embodiments, when the water drop angle of the surface of the side of the cover layer 102 contacting the first bonding layer 103 is greater than or equal to 100 degrees, the cover layer 102 further comprises a second sublayer 121, and a side of the second sublayer 121 near the first bonding layer 103 contacting the first bonding layer 103. Namely, a water drop angle of a surface of a side of the second sublayer 121 contacting the first bonding layer 103 is greater than or equal to 100 degrees.

In some embodiments, the second sublayer 121 can be an anti-fingerprint coating layer comprising oil resistance, anti-fingerprint, waterproof and other properties.

In some embodiments, material of the second sublayer 121 can be selected from at least one of fluorine-containing inorganic material and fluorine-containing organic material. For example, the material of the second sublayer 121 can be selected from fluorosilicates.

With reference to FIGS. 2 to 5, in some embodiments, the cover layer 102 further comprises a substrate sublayer 104, and the substrate sublayer 104 is located between the protection sublayer 105 and the first bonding layer 103. When the cover layer 102 comprises the second sublayer 121, the substrate sublayer 104 is located between the second sublayer 121 and the protection sublayer 105. When the cover layer 102 does not comprise the second sublayer 121, the substrate sublayer 104 is located between the protection sublayer 105 and the first bonding layer 103, and a side of the substrate sublayer 104 near the first bonding layer 103 contacts the first bonding layer 103.

With reference to FIGS. 2 to 6, in some embodiments, the cover layer 102 further comprises a third sublayer 106, the protection sublayer 105 is located between the third sublayer 106 and the substrate sublayer 104. A hardness of a surface of a side of the third sublayer 106 away from the substrate sublayer 104 is less than or equal to a hardness of a surface of a side of the protection sublayer 105 away from the substrate sublayer 104. Alternatively, the hardness of the surface of the side of the third sublayer 106 away from the substrate sublayer 104 is greater than the hardness of the surface of the side of the protection sublayer 105 away from the substrate sublayer 104. The configuration of the third sublayer 106, while employing the protection sublayer 105 to improve the hardness of the side of the cover layer 102 away from the display layer 101 (namely, the side of the cover layer 102 contacted by the user), employs the third sublayer 106 to protect the protection sublayer 105 and reduce a risk of breaking the protection sublayer 105.

With reference to FIGS. 2 to 6, in some embodiments, the third sublayer 106 is located on an outermost side of the cover layer 102 away from the display layer 101. Namely, the surface of the side of the third sublayer 106 away from the substrate sublayer 104 is an outermost side surface of the display panel 100 on the light exiting side of the display layer 101. The configuration of the third sublayer 106 facilitates protecting the protection sublayer 105 and preventing fragments generated by the protection sublayer 105 from injuring the user when the protection sublayer 105 shatters, which improves the safety of using the display panel 100.

In some embodiments, the hardness of the surface of the side of the third sublayer 106 away from the substrate sublayer 104 is greater than a hardness of a surface of a side of the third sublayer 106 near the substrate sublayer 104. Namely, the hardness of the surface of the side of the third sublayer 106 near the substrate sublayer 104 is lower, the hardness of the surface of the side of the third sublayer 106 away from the substrate sublayer 104 is higher, thereby preventing fragments generated by the protection sublayer 105 from injuring the user when the protection sublayer 105 shatters during usage to enhance safety of using the display panel 100, while further enhancing the user's feeling of use and reducing surface scratches.

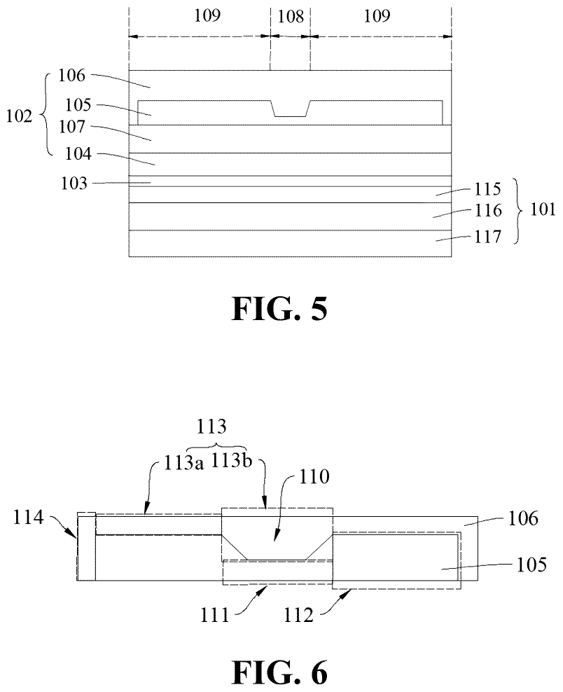

With reference to FIGS. 5 to 6, in some embodiments, an orthographic projection of the protection sublayer 105 on the substrate sublayer 104 is located within the orthographic projection of the third sublayer 106 on the substrate sublayer 104, thereby facilitating improving the protection effect to the protection sublayer 105 and the safety of using the display panel 100.

With reference to FIGS. 5 to 6, in some embodiments, the protection sublayer 105 comprises at least one of side surfaces located between the surface of the side of the protection sublayer 105 away from the substrate sublayer 104 and the surface of a side of the protection sublayer 105 near the substrate sublayer 104. The third sublayer 106 covers at least one of the side surfaces of the protection sublayer 105, which prevents the protection sublayer 105 being broken due to cutting when the cover layer 102 is formed by the cutting, while improving the third sublayer 106 the protection effect to the protection sublayer 105, to improve the product yield of the display panel 100. Preferably, the third sublayer 106 covers each of the side surfaces of the protection sublayer 105.

In some embodiments, the hardness of the surface of the side of the third sublayer 106 away from the substrate sublayer 104 is greater than a hardness of a surface of a side the substrate sublayer 104 near the third sublayer 106, thereby facilitating improving the surface hardness of the side of the cover layer 102 away from display layer 101, enhancing the user's feeling of use, reducing surface scratches, and improving the product quality of the display panel 100.

In some embodiments, the surface of the side of the third sublayer 106 away from the substrate sublayer 104 hardness is greater than or equal to 3H, the surface of the side of the third sublayer 106 away from the substrate sublayer 104 hardness is less than or equal to 9H, for example, and can be 4H, 5H, 6H, 7H, 8H, etc.

In some embodiments, the third sublayer 106 can be a hard coating layer. Material of the third sublayer 106 can be composite material including mutually doped or mixed organic matter and inorganic mater. Material of the third sublayer 106 can be selected from silicon-containing inorganic-organic material. For example, the material of the third sublayer 106 can be selected from at least one of composite material comprising silicon oxide and/or silicon nitride, siloxane and acrylic polymer, semi-siloxane polymer, aliphatic or aromatic polymers containing inorganic silicon group. When the third sublayer 106 is selected from composite material including mutually doped or mixed organic matter and inorganic matter, the surface of the side of the third sublayer 106 away from the substrate sublayer 104 has a higher surface hardness and a better restoring performance. For example, when the material of the third sublayer 106 is selected from polymers including siloxane, because such material has a better restoring performance, when a stylus or other harder object is used to slide on a surface of a side of the third sublayer 106 away from the display layer 101 with a greater force, subtle marks may be left on the surface. When the stylus or other harder object leaves the surface, subtle marks would be restored and disappear.

In some embodiments, the protection sublayer 105 can comprise ultra-thin glass (UTG), or other organic material having a certain hardness and able to perform a supporting function to fulfill a requirement to a bending performance of the display panel 100 while enhancing the surface hardness of the side of the cover layer 102 away from the display layer 101.

In some embodiments, the hardness of the surface of the side of the protection sublayer 105 away from the substrate sublayer 104 is greater than or equal to 6H, the hardness of the surface of the side of the protection sublayer 105 away from the substrate sublayer 104 is less than or equal to 9H. For example, the hardness can be 6.2H, 6.3H, 6.4H, 6.5H, 6.6H, 6.7H, 6.8H, 6.9H, 7H, 7.2H, 7.3H, 7.4H, 7.5H, 7.6H, 7.7H, 7.8H, 7.9H, 8.2H, 8.3H, 8.4H, 8.5H, 8.6H, 8.7H, 8.8H, 8.9H, etc.

With reference to FIGS. 2 to 5, in some embodiments, the cover layer 102 further comprises a second bonding layer 107 located between the substrate sublayer 104 and the protection sublayer 105. The second bonding layer 107 securely bonds the protection sublayer 105 and the substrate sublayer 104. When the third sublayer 106 covers at least one of the side surfaces of the protection sublayer 105, the surface of the side of the third sublayer 106 near the substrate sublayer 104 partially contacts the second bonding layer 107.

In some embodiments, the first bonding layer 103, material of the second bonding layer 107 can be selected from an optical adhesive with a higher light transmittance.

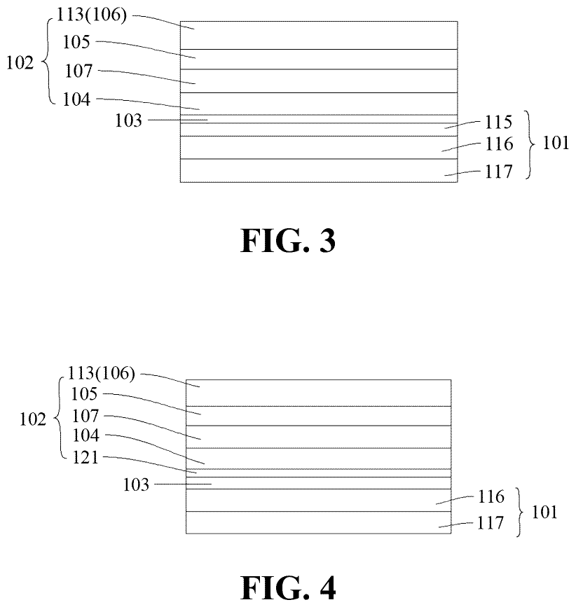

With reference to FIGS. 2 to 3, in some embodiments, the surface of the side of the protection sublayer 105 away from the substrate sublayer 104 is parallel to a plane in which the substrate sublayer 104 is located. Namely, the surface of the side of the protection sublayer 105 away from the substrate sublayer 104 is a flat surface. The surface of the side of the protection sublayer 105 near the substrate sublayer 104 is parallel to the plane in which the substrate sublayer 104 is located. Namely, the surface of the side of the protection sublayer 105 near the substrate sublayer 104 is a flat surface. An interval between the surface of the side of the protection sublayer 105 near the substrate sublayer 104 and the surface of the side of the protection sublayer 105 away from the substrate sublayer 104 is a thickness of the protection sublayer 105. The thickness of the protection sublayer 105 is greater than or equal to 25 microns. The thickness of the protection sublayer 105 is less than or equal to 50 microns. For example, the thickness can be 30 microns, 32 microns, 35 microns, 37 microns, 40 microns, 42 microns, 45 microns, 47 microns, etc.

With reference to FIGS. 2 to 3, in some embodiments, when the surface of the side of the protection sublayer 105 away from the substrate sublayer 104 is parallel to the plane in which the substrate sublayer 104 is located, the third sublayer 106 comprises a first portion 113, an orthographic projection of the first portion 113 on the substrate sublayer 104 is located in the orthographic projection of the protection sublayer 105 on the substrate sublayer 104. A surface of a side of the first portion 113 near the substrate sublayer 104 is parallel to the plane in which the substrate sublayer 104 is located, and a surface of a side of the first portion 113 away from the substrate sublayer 104 is parallel to the plane in which the substrate sublayer 104 is located. An interval between the surface of the side of the first portion 113 near the substrate sublayer 104 and the surface of the side of the first portion 113 away from the substrate sublayer 104 is a thickness of the first portion 113. The thickness of the first portion 113 is less than the thickness of the protection sublayer 105 to increase a surface hardness of a side of the cover layer 102 away from the substrate sublayer 104, enhance the user's feeling of use, and reduce surface scratches, which improves the product quality of the display panel 100.

In some embodiments, when the surface of the side of the first portion 113 near the substrate sublayer 104 is parallel to the plane in which the substrate sublayer 104 is located and the surface of the side of the first portion 113 away from the substrate sublayer 104 is parallel to the plane in which the substrate sublayer 104 is located, a ratio of the thickness of the first portion 113 to the thickness of the protection sublayer 105 is greater than or equal to 0.4, and a ratio of the thickness of the first portion 113 to the thickness of the protection sublayer 105 is less than or equal to 0.8. For example, the ratio can be 0.5, 0.55, 0.56, 0.58, 0.6, 0.65, 0.66, 0.67, 0.7, 0.72, 0.75, 0.78, etc., to adjust the surface hardness of the side of the cover layer 102 away from the display layer 101, and the protection performance of the third sublayer 106 to the protection sublayer 105.

In some embodiments, the thickness of the first portion 113 is greater than or equal to 16 microns, and the thickness of the first portion 113 is less than or equal to 24 microns. For example, the thickness can be 17 microns, 18 microns, 19 microns, 20 microns, 21 microns, 22 microns, 23 microns, etc.

With reference to FIGS. 5 to 6, in some embodiments, when the third sublayer 106 covers at least one of the side surfaces of the protection sublayer 105, the third sublayer 106 further comprises a second portion 114, and an orthographic projection of the second portion 114 on the substrate sublayer 104 is located outside the orthographic projection of the protection sublayer 105 on the substrate sublayer 104. The second portion 114 covers at least one of the side surfaces of the protection sublayer 105. A thickness of the second portion 114 is equal to a sum of the thicknesses of the first sublayer and the protection sublayer 105 such that the surface of the side of the third sublayer 106 away from the substrate sublayer 104 is parallel to a plane in which the substrate sublayer 104 is located. The thickness of the second portion 114 is greater than or equal to 41 microns. The thickness of the second portion 114 is less than or equal to 74 microns. For example, the thickness can be 42 microns, 45 microns, 46 microns, 48 microns, 50 microns, 52 microns, 55 microns, 58 microns, 60 microns, 62 microns, 65 microns, 68 microns, 70 microns, 72 microns, etc.

With reference to FIGS. 5 and 6, in some embodiments, the display panel 100 further comprises a bending sub-region 108 located in a display region. The protection sublayer 105 comprises at least one recess 110, and the recess 110 is located on a side of the protection sublayer 105 away from the substrate sublayer 104. The recess 110 is located in the bending sub-region 108. The configuration of the recess 110 facilitates improving the bending performance of the cover layer 102.

In some embodiments, the recess 110 is located on the side of the protection sublayer 105 away from the substrate sublayer 104. A depth of the recess 110 is less than the thickness of the protection sublayer 105. Namely, the protection sublayer 105 with a certain thickness is still located between a side of the recess 110 near the substrate sublayer 104 and the side of the protection sublayer 105 near the substrate sublayer 104 to maintain a support performance of the protection sublayer 105 while improving the bending performance of the cover layer 102.

With reference to FIG. 5, in some embodiments, the recesses 110 correspond to the bending sub-regions 108 of the display panel 100 one by one. Namely, one recess 110 is located in one bending sub-region 108.

In some embodiments, the recess 110 comprises a sidewall connected to the side of the recess 110 near the substrate sublayer 104 and a side of the recess 110 away from the substrate sublayer 104. An extension direction of an orthographic projection of the sidewall on the substrate sublayer 104 is parallel to an extension direction of the bending sub-region 108.

With reference to FIG. 6, in some embodiments, the protection sublayer 105 further comprises a first thickness portion 111 and a second thickness portion 112. The first thickness portion 111 is located in an orthographic projection of the recess 110 on the substrate sublayer 104. The second thickness portion 112 is located outside the orthographic projection of the recess 110 on the substrate sublayer 104.

With reference to FIG. 5, in some embodiments, the display panel 100 further comprises a non-bending sub-region 109 connected to the bending sub-region 108. The first thickness portion 111 is located in the bending sub-region 108. The second thickness portion 112 is at least partially located in the non-bending sub-region 109. A thickness of the second thickness portion 112 is greater than a minimum thickness of the first thickness portion 111, which facilitates improving the surface hardness of the side of the cover layer 102 away from display layer 101 in the non-bending sub-region 109, enhancing the user's feeling of use, and reducing surface scratches while guaranteeing the bending performance of the display panel 100, to improve the product quality of the display panel 100.

In some embodiments, the minimum thickness of the first thickness portion 111 is greater than or equal to 30 microns, the minimum thickness of the first thickness portion 111 is less than or equal to 50 microns. For example, the minimum thickness can be 32 microns, 35 microns, 36 microns, 40 microns, 42 microns, 45 microns, 46 microns, 48 microns, etc.

In some embodiments, the thickness of the second thickness portion 112 is greater than or equal to 70 microns, the thickness of the second thickness portion 112 is less than or equal to 120 microns. For example, the thickness can be 75 microns, 80 microns, 85 microns, 90 microns, 95 microns, microns, 105 microns, 110 microns, 115 microns, etc.

With reference to FIG. 6, in some embodiments, when the protection sublayer 105 comprises the first thickness portion 111 and the second thickness portion 112, the first portion 113 of the third sublayer 106 comprises a flat sub-portion 113a and a fill sub-portion 113b. The flat sub-portion 113a covers a side of the second thickness portion 112 away from the substrate sublayer 104. The fill sub-portion 113b covers a side of the first thickness portion 111 away from the substrate sublayer 104.

In some embodiments, a thickness of the flat sub-portion 113a is greater than or equal to 16 microns. A thickness of the fill sub-portion 113b is less than or equal to 24 microns. For example, the thickness can be 17 microns, 18 microns, 19 microns, 20 microns, 21 microns, 22 microns, 23 microns, etc.

In some embodiments, the thickness of the fill sub-portion 113b is greater than or equal to 36 microns. The thickness of the fill sub-portion 113b is less than or equal to microns. For example, the thickness can be 40 microns, 45 microns, 50 microns, 55 microns, 60 microns, 65 microns, 70 microns, 75 microns, 80 microns, 85 microns, 90 microns, 95 microns, microns, 105 microns, 110 microns, etc.

In some embodiments, when the display panel 100 comprises the bending sub-region 108, the display panel 100 comprises a bending state and a flat expanding state. The display panel 100 can be a folding display panel 100. A sum of the thickness of the first thickness portion 111 and the thickness of the fill sub-portion 113b is equal to a sum of the thickness of the second thickness portion 112 and the thickness of the flat sub-portion 113a. Namely, when the display panel 100 is in the flat expanding state, the surface of the side of the third sublayer 106 away from the substrate sublayer 104 is parallel to the plane in which the substrate sublayer 104 is located, and the surface of the side of the protection sublayer 105 away from the substrate sublayer 104 is parallel to the plane in which the substrate sublayer 104 is located. Preferably, the sum of the thickness of the first thickness portion 111 and the thickness of the fill sub-portion 113b is greater than or equal to 72 microns, and the sum of the thickness of the first thickness portion 111 and the thickness of the fill sub-portion 113b is less than or equal to 110 microns. For example, the sum of the thicknesses can be 75 microns, 80 microns, 85 microns, 90 microns, 92 microns, 95 microns, 96 microns, microns, 105 microns, etc.

In some embodiments, material of the substrate sublayer 104 can be selected from at least one of polymers with optical properties including a high light transmittance such as polyethylene terephthalate (PETE), polyimide, thermoplastic polyurethane (TPU).

In some embodiments, a thickness of the substrate sublayer 104 is greater than or equal to 20 microns, the thickness of the substrate sublayer 104 is less than or equal to 50 microns. For example, the thickness can be 22 microns, 25 microns, 28 microns, 30 microns, 32 microns, 35 microns, 38 microns, 40 microns, 42 microns, 45 microns, 48 microns, etc.

With reference to Table 1, Table 1 is a performance data result for impact resistance and abrasion resistance of the display panel provided by the embodiment of the present application.

TABLE 1
Data of impact resistance and abrasion resistance of the display panel

| | Pen/cm | | Ball/cm | | |
|---|---|---|---|---|---|
| | | Non-bending | | Non-bending | |
| | Bending | sub-region | Bending | sub-region | |
| | sub-region | 109 | sub-region | 109 | Scratches |
| Embodiment | 4 | 4-5 | 4 | 7-9 | No obvious |
| 1 | | | | | scratch over |
| | | | | | 2000 times |
| Comparison | 5-7 | 6-10 | 4-5 | 9-16 | |
| example 1 | | | | | |

The embodiment 1 and the comparison example 1 are experimental group and control group including the same test conditions. The display panel in the embodiment 1 utilizes the display panel provided by the embodiment of the present invention, and the display panel in the comparison example 1 utilizes a conventional display panel. A difference therebetween is that the cover layer in the embodiment 1 is composed of a substrate sublayer, a second bonding layer, a protection sublayer, and a third sublayer, and the cover layer in the comparison example 1 is composed of two polymer layers including a hard protective layer and a first polymer protective layer and a second polymer protective layer that are located on a side of the hard protective layer away from display layer, and the hard protective layer and the display layer cannot be separated. The protection sublayer of the cover layer in the embodiment 1 is structurally the same as the hard protective layer in the comparison example 1. Also, under the flat expanding state of the display panel, a surface of a side of cover layer in the embodiment 1 away from display layer is parallel to a display surface of the display panel, and a surface of a side of the cover layer in the comparison example 1 away from display layer is parallel to a display surface of the display panel.

It can be understood from the data in Table 1, the display panel provided by the embodiment of the present invention has results of the pent test and the ball test similar to those of the conventional display panel provided by, and no scratch is formed after the stylus is used to repeatedly slide on the outermost side surface of the cover layer by 2000 times, so the display panel provided by the embodiment of the present invention has better impact resistance and excellent abrasion resistance.

In some embodiments, the display layer 101 comprises a plurality of functional film layers for display in the display panel 100.

With reference to FIG. 2, in some embodiments, the display layer 101 further comprises a polarization layer 116 and a display panel main body layer 117. The polarization layer 116 is located on a side of the display panel main body layer 117 near the cover layer 102. The first sublayer 115 can be formed on a surface of a side of the polarization layer 116 near the first bonding layer 103. Namely, the first sublayer 115 is located on the side of the polarization layer 116 near the first bonding layer 103, and the first sublayer 115 contacts the polarization layer 116.

In some embodiments, the display panel main body layer 117 further comprises an underlay located away from a side of the cover layer 102. The underlay can be a hard underlay, for example, a glass underlay. Alternatively, the underlay can be a flexible underlay, for example, the underlay can be an underlay formed by polyimide. When the underlay is a flexible underlay, the underlay can be formed by multiple layers of sub-underlays of the same material such as polyimide, and adjacent ones of the sub-underlays are bonded by a bonding sublayer.

In some embodiments, the display panel main body layer 117 further comprises a thin film transistor layer located between the underlay and the first sublayer 115. The thin film transistor layer comprises a thin film transistor. The thin film transistor comprises a semiconductor located on the underlay. The semiconductor can be formed by polycrystalline silicon or metal oxide (for example, indium gallium zinc oxide). The semiconductor is divided into a channel region and a source electrode region and a drain electrode region formed on two sides of the channel region. The thin film transistor layer further comprises a first gate electrode insulation layer. The first gate electrode insulation layer covers the semiconductor. The thin film transistor further comprises a first gate electrode formed on the first gate electrode insulation layer, and the first gate electrode overlaps the channel region. The first gate electrode can be formed as a plurality of layers or a single layer including material of low resistance such as Al, Ti, Mo, Cu, Ni, or an alloy thereof, or material of an anti-corrosion performance. The thin film transistor layer further comprises a second gate electrode insulation layer, and the second gate electrode insulation layer covers the first gate electrode. The thin film transistor further comprises a second gate electrode located on the second gate electrode insulation layer, and the second gate electrode overlaps the first gate electrode. The second gate electrode can be formed as a plurality of layers or a single layer including material of low resistance such as Al, Ti, Mo, Cu, Ni, or an alloy thereof, or material of an anti-corrosion performance. The thin film transistor layer further comprises a first interlayer insulation layer formed on the second gate electrode. The first interlayer insulation layer, the first gate electrode insulation layer, and the second gate electrode insulation layer comprise a source electrode contact hole and a drain electrode contact hole. The source electrode region and the drain electrode region are exposed by the source electrode contact hole and the drain electrode contact hole, respectively.

The thin film transistor further comprises a source electrode and a drain electrode disposed in the same layer and both formed on the first interlayer insulation layer. The source electrode extends through the source electrode contact hole and is connected to the source electrode region, and the drain electrode extends through the drain electrode contact hole and is connected to the drain electrode region. The source electrode and the drain electrode can be a plurality of layers or a single layer formed by material of low resistance such as Al, Ti, Mo, Cu, Ni, or an alloy thereof, or material of an anti-corrosion performance. For example, the source electrode and the drain electrode can be a triple-layer including Ti/Cu/Ti, Ti/Ag/Ti, Ti/Al/Ti, or Mo/Al/Mo or other single layer structure or multi-layer layer structure.

In some embodiments, the display panel main body layer 117 further comprises a planarization layer located between the thin film transistor layer and the light emitting layer, and the planarization layer covers the source electrode and the drain electrode.

In some embodiments, the display panel main body layer 117 further comprises an anode layer located between the planarization layer and the first sublayer 115, the anode layer comprises a plurality of anodes, and the anodes correspond to the pixel units one by one. Each of the anodes is electrically connected to the thin film transistor. The planarization layer comprises an anode contact hole, and the anode contacts a source electrode or a drain electrode of the thin film transistor by the anode contact hole.

In some embodiments, the display panel main body layer 117 further comprises a pixel definition layer, and the pixel definition layer and the pixel units are located on the same side of the underlay. The pixel definition layer comprises pixel definition portions and apertures located among the pixel definition portion. The display panel main body layer 117 further comprises a light emitting layer, the light emitting layer comprises a plurality of pixel units. The pixel units are located in the apertures. The aperture partially exposes the anode and covers an edge of the anode. The pixel unit can comprise a red pixel unit, a green pixel unit, and a blue pixel unit.

In some embodiments, the cathode layer covers the light emitting layer. Along a direction from the anode to the cathode layer, the light emitting layer comprises a hole organic layer, a light emitting material layer, and an electron organic layer sequentially stacked on one another. The hole organic layer can comprise a hole injection layer and a hole transport layer. The hole injection layer directly contacts the anode. The hole transport layer is located between the hole injection layer and the light emitting material layer. The hole organic layer can further comprise an electron barrier layer located between the hole transport layer and the light emitting material layer. The electron organic layer can comprise an electron injection layer and an electron transport layer. The electron injection layer directly contacts the cathode layer. The electron transport layer is located between the electron injection layer and the light emitting material layer. The electron organic layer can further comprise a hole barrier layer located between the electron transport layer and the light emitting layer.

In some embodiments, the display panel main body layer 117 further comprises an encapsulation layer located on a side of the cathode layer near the cover layer 102. The encapsulation layer is formed by a plurality of inorganic film layers and organic film layers that are alternately stacked. For example, along a direction from the display layer 101 to the cover layer 102, the encapsulation layer comprises a first inorganic encapsulation sublayer, a first organic encapsulation sublayer, and a second inorganic encapsulation sublayer.

In some embodiments, the display panel main body layer 117 further comprises a touch layer located on a side of the encapsulation layer away from the light emitting layer. A method for the touch layer to implement a touch function can be self-capacitance touch or mutual capacitance touch. When the method for the touch layer to implement a touch function is the self-capacitance touch, the touch layer can have only one touch metal layer.

When the method for the touch layer to implement a touch function is the mutual capacitance touch, the touch layer comprises a first touch metal layer, a touch insulation layer, and a second touch metal layer. The touch insulation layer is located on a side of the first touch metal layer away from the encapsulation layer, and the second touch metal layer is located on a side of the touch insulation layer away from the encapsulation layer. The first touch metal layer can be directly disposed on the encapsulation layer. Alternatively, an interlayer layer is further disposed between the first touch layer and the encapsulation layer. The interlayer layer can comprise an inorganic interlayer layer and/or an organic interlayer layer. The first touch metal layer comprises a first touch electrode, a second touch electrode, and a first bridge line. The second touch metal layer comprises a second bridge line. Both the first touch electrode and the second touch electrode are metal networks. Alternatively, the second touch metal layer comprises a first touch electrode, a second touch electrode, and a first bridge line. The first touch metal layer comprises a second bridge line.

With reference to FIG. 2, in some embodiments, the display panel 100 further comprises a backplate layer 118 located a side of the underlay away from the cover layer 102, a light shielding layer 119 located on a side of the backplate layer 118 away from the underlay, and a support layer 120 located on a side of the light shielding layer 119 away from the underlay. The backplate layer 118 can be set to be made of easily bending material, for example, material such as polyimide, to keep the bending performance of the display panel 100. Alternatively, the backplate layer 118 and the support layer 120 can utilize the same material. Material of the light shielding layer 119 can be selected from easily bending black material, for example, material such as black polyimide. Material of the support layer 120 can be selected from metal material having a better heat dissipation performance, for example, the support layer 120 can be selected from material such as stainless steel. Both the support layer 120 and the backplate layer 118 can perform certain fastening and supporting functions.

The display panel provided by the embodiment of the present invention 100 disposes the protection sublayer 105 with a greater hardness on a side of the substrate sublayer 104 of the cover layer 102 away from the first bonding layer 103, which enhances the surface hardness on a side of the cover layer 102 away from the display layer 101, enhances the user's feeling of use, and reduces surface scratches while lowering removal difficulty of the cover layer 102, and thus to improve the product quality of the display panel 100.

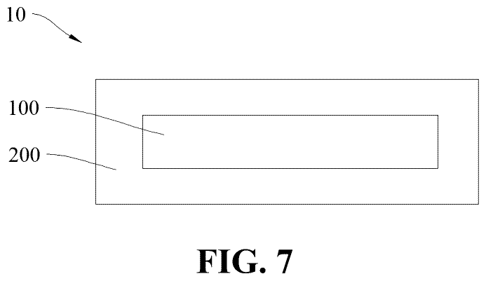

With reference to FIG. 7, the embodiment of the present invention further provides a display device 10, comprising any one of the above display panels 100.

Specific structures of the display panel 100 shall refer to any one of the above embodiments of the display panel and the accompanying drawings, and no repeated description is here.

In some embodiments, the display device 10 further comprises a device main body 200, and the device main body 200 and the display panel 100 are assembled integrally.

In some embodiments, the device main body 200 can comprise a middle frame, a frame sealant, etc., the display device 10 can be a display terminal such as a cell phone, a tablet, a television, etc., and no limit is applied thereto.

The embodiment of the present invention discloses a display panel and a display device. The display panel comprises a display layer, a cover layer and a first bonding layer, and the first bonding layer is located between the display layer and the cover layer. The cover layer comprises a protection sublayer, the protection sublayer is located on a side of the first bonding layer away from the display layer. A hardness of a surface of a side of the protection sublayer away from the first bonding layer is greater than or equal to 6H and is less than or equal to 9H. A water drop angle of a surface of the cover layer and/or the display layer contacting the first bonding layer is greater than or equal to 100 degrees. The present invention disposes the protection sublayer with the greater hardness on the cover layer and makes the water drop angle of the surface of the cover layer and/or display layer contacting the first bonding layer greater than or equal to 100 degrees, which improves the surface hardness of a side of the cover layer away from display layer, enhances the user's feeling of use, and reduces surface scratches while lowering the removal difficulty of the cover layer, and thus improves the product quality of the display panel.

It can be understood that for a person of ordinary skill in the art, equivalent replacements or changes can be made according to the technical solution of the present application and its inventive concept, and all these changes or replacements should belong to the scope of protection of the appended claims of the present application.

1. A display panel, comprising:
a display layer;
a cover layer located on a light exiting side of the display layer; and
a first bonding layer located between the display layer and the cover layer;
wherein the cover layer comprises a protection sublayer, the protection sublayer is located on a side of the first bonding layer away from the display layer, a hardness of a surface of a side of the protection sublayer away from the first bonding layer is greater than or equal to 6H, and the hardness of the surface of the side of the protection sublayer away from the first bonding layer is less than or equal to 9H;
wherein a water drop angle of a surface of a side of the cover layer contacting the first bonding layer is greater than or equal to 100 degrees, and/or, a water drop angle of a surface of a side of the display layer contacting the first bonding layer is greater than or equal to 100 degrees.

2. The display panel according to claim 1, wherein a water drop angle of a surface of the display layer contacting the first bonding layer is greater than or equal to 100 degrees, the water drop angle of the surface of the side of the cover layer contacting the first bonding layer is greater than or equal to 20 degrees, the water drop angle of the surface of the side of the cover layer contacting the first bonding layer is less than or equal to 50 degrees.

3. The display panel according to claim 2, wherein the display layer comprises a first sublayer, a side of the first sublayer near the first bonding layer contacts the first bonding layer, and material of the first sublayer comprises fluorine-containing inorganic material.

4. The display panel according to claim 1, wherein the water drop angle of the surface of the side of the cover layer contacting the first bonding layer is greater than or equal to 100 degrees, the cover layer further comprises a second sublayer, a side of the second sublayer near the first bonding layer contacts the first bonding layer, and material of the second sublayer comprises fluorine-containing inorganic material.

5. The display panel according to claim 1, wherein the cover layer further comprises a substrate sublayer, and the substrate sublayer is located between the protection sublayer and the first bonding layer; and
a hardness of a surface of a side of the substrate sublayer away from the first bonding layer is less than the surface of the hardness of the side of the protection sublayer away from the first bonding layer.

6. The display panel according to claim 5, wherein the cover layer further comprises a third sublayer, the protection sublayer is located between the third sublayer and the substrate sublayer; and
a hardness of a surface of a side of the third sublayer away from the substrate sublayer is less than or equal to a hardness of a surface of a side of the protection sublayer away from the substrate sublayer.

7. The display panel according to claim 6, wherein the hardness of the surface of the side of the third sublayer away from the substrate sublayer is greater than a hardness of a surface of a side of the third sublayer near the substrate sublayer.

8. The display panel according to claim 6, wherein an orthographic projection of the protection sublayer on the substrate sublayer is located within an orthographic projection of the third sublayer in the substrate sublayer.

9. The display panel according to claim 6, wherein the surface of the side of the protection sublayer away from the substrate sublayer parallel to a plane in which the substrate sublayer is located, a surface of a side of the protection sublayer near the substrate sublayer is parallel to the plane in which the substrate sublayer is located, a thickness of the protection sublayer is greater than or equal to 25 microns, and the thickness of the protection sublayer is less than or equal to 50 microns.

10. The display panel according to claim 6, wherein the protection sublayer comprises at least one of side surfaces located between the surface of the side of the protection sublayer away from the substrate sublayer and a surface of a side of the protection sublayer near the substrate sublayer, and the third sublayer covers at least one of the side surfaces of the protection sublayer.

11. The display panel according to claim 6, wherein the display panel further comprises a bending sub-region located in a display region, the protection sublayer comprises at least one recess, the recess is located on the side of the protection sublayer away from the substrate sublayer, and the recess is located in the bending sub-region.

12. The display panel according to claim 11, wherein the protection sublayer further comprises a first thickness portion and a second thickness portion, the first thickness portion is located in an orthographic projection of the recess on the substrate sublayer, and the second thickness portion is located outside the orthographic projection of the recess on the substrate sublayer;
wherein a minimum thickness of the first thickness portion is greater than or equal to 30 microns, and the minimum thickness of the first thickness portion is less than or equal to 50 microns;
a thickness of the second thickness portion is greater than or equal to 70 microns, and the thickness of the second thickness portion is less than or equal to 120 microns.

13. A display device, comprising a display panel, and the display panel comprising:
a display layer;
a cover layer located on a light exiting side of the display layer; and
a first bonding layer located between the display layer and the cover layer;
wherein the cover layer comprises a protection sublayer, the protection sublayer is located on a side of the first bonding layer away from the display layer, a hardness of a surface of a side of the protection sublayer away from the first bonding layer is greater than or equal to 6H, and the hardness of the surface of the side of the protection sublayer away from the first bonding layer is less than or equal to 9H;
wherein a water drop angle of a surface of a side of the cover layer contacting the first bonding layer is greater than or equal to 100 degrees, and/or, a water drop angle of a surface of a side of the display layer contacting the first bonding layer is greater than or equal to 100 degrees.

14. The display device according to claim 13, wherein a water drop angle of a surface of the display layer contacting the first bonding layer is greater than or equal to 100 degrees, the water drop angle of the surface of the side of the cover layer contacting the first bonding layer is greater than or equal to 20 degrees, the water drop angle of the surface of the side of the cover layer contacting the first bonding layer is less than or equal to 50 degrees.

15. The display device according to claim 14, wherein the display layer comprises a first sublayer, a side of the first sublayer near the first bonding layer contacts the first bonding layer, and material of the first sublayer comprises fluorine-containing inorganic material.

16. The display device according to claim 13, the water drop angle of the surface of the side of the cover layer contacting the first bonding layer is greater than or equal to 100 degrees, the cover layer further comprises a second sublayer, a side of the second sublayer near the first bonding layer contacts the first bonding layer, and material of the second sublayer comprises fluorine-containing inorganic material.

17. The display device according to claim 13, wherein the cover layer further comprises a substrate sublayer, and the substrate sublayer is located between the protection sublayer and the first bonding layer; and
a hardness of a surface of a side of the substrate sublayer away from the first bonding layer is less than the surface of the hardness of the side of the protection sublayer away from the first bonding layer.

18. The display device according to claim 17, wherein the cover layer further comprises a third sublayer, the protection sublayer is located between the third sublayer and the substrate sublayer; and
a hardness of a surface of a side of the third sublayer away from the substrate sublayer is less than or equal to a hardness of a surface of a side of the protection sublayer away from the substrate sublayer.

19. The display device according to claim 18, wherein the hardness of the surface of the side of the third sublayer away from the substrate sublayer is greater than a hardness of a surface of a side of the third sublayer near the substrate sublayer.

20. The display device according to claim 18, wherein an orthographic projection of the protection sublayer on the substrate sublayer is located within an orthographic projection of the third sublayer in the substrate sublayer.
